(19) United States
(12) Patent Application Publication
(10) Pub. No.: US 2010/0129983 A1
(43) Pub. Date: May 27, 2010

(54) Method of Fabricating Semiconductor Device

(76) Inventor: Jeong Ho PARK, Icheon-si (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/619,082

(22) Filed: Nov. 16, 2009

(30) Foreign Application Priority Data
Nov. 26, 2008 (KR) 10-2008-0118026

(51) Int. Cl. H01L 21/762

(52) U.S. Cl. 438/435; 257/E21.546

(57) ABSTRACT

Methods of fabricating a semiconductor device that is capable of reducing and/or maintaining a proper divot depth at the corners of a device isolation layer. The method includes forming a pad oxide layer and a pad nitride layer sequentially on a semiconductor substrate, forming a trench by selectively etching the pad oxide layer, the pad nitride layer and the semiconductor substrate, depositing an insulating layer in the trench, selectively etching the pad nitride layer and the insulating layer by performing a first etching process, removing the pad nitride layer by performing a second etching process, and forming a gate polysilicon layer over the entire surface of the semiconductor substrate.

### CROSS REFERENCE TO RELATED APPLICATION

This application claims the benefit of Korean Patent Application No. 10-2008-0118026, filed on Nov. 26, 2008 which is hereby incorporated by reference as if fully set forth herein.

### BACKGROUND OF THE INVENTION

1. Field of the Invention

The present invention relates to a method of fabricating a semiconductor device, and more particularly, to a method of fabricating a semiconductor device capable of maintaining a proper divot depth of a device isolation layer.

2. Discussion of the Related Art

Recently, according to advancement of the semiconductor device fabricating technology and expansion of the fields of application of the technology, research and development for improving a degree of integration of semiconductor devices are in progress. Such an improvement in the integration of the semiconductor device has pushed research into development of nano-scale semiconductor devices. One significant factor in developing the nano-scale technology for semiconductor devices is reduction of the size of a device isolation layer which isolates devices, and thus facilitates device integration.

Generally, local oxidation of silicon (LOCOS) technology has been used as a device isolation method, in which a silicon wafer is thermally oxidized using a nitride layer as a mask. Thus, the LOCOS device isolation method has the advantage of being a relatively simple process for forming an isolation oxide layer.

However, the LOCOS device isolation method cannot be used in a nano-scale semiconductor device because a LOCOS device isolation region occupies a large area. Furthermore, the LOCOS method may generate a bird's beak at corners of an isolation trench. Shallow trench isolation (STI) technology was developed to overcome the above conventional problems as a substitute for the LOCOS method.

According to the STI method, a deep and narrow trench is formed through dry etching such as reactive ion etching (RIE) and plasma etching, and the trench is then filled with an oxide layer. Since an insulating material is put in a trench formed on a silicon wafer, the bird's beak phenomenon may be avoided. In addition, since a surface of the silicon wafer and/or the oxide layer are planarized after the oxide is deposited in the trench, the area occupied by the device isolation layer may be reduced, which allows for the application of STI technology to nano-scale semiconductor devices.

However, according to the general STI method, a divot may result at upper corners of the isolation trench and the isolation oxide layer, having a due to etching of the isolation layer during a wet etch after a isolation layer and an STI chemical mechanical polishing (CMP) process are sequentially performed. Therefore, an STI gap-filling oxide layer may be partially removed at the upper corners of the isolation trench. As shown in FIG. 1, a polysilicon or oxidized polysilicon residue 1 may remain where the STI oxide layer is lost during formation of a gate.

### SUMMARY OF THE INVENTION

Accordingly, the present invention is directed to a method of fabricating a semiconductor device that substantially obviates one or more problems due to limitations and disadvantages of the related art.

An object of the present invention is to provide a method of fabricating a semiconductor device, capable of maintaining a proper divot depth of a device isolation layer.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of fabricating a semiconductor device includes forming a pad oxide layer and a paid nitride layer sequentially on a semiconductor substrate, forming a trench by selectively etching the pad oxide layer, the pad nitride layer and the semiconductor substrate, filling an inside of the trench by depositing an insulating layer in the trench, selectively etching the pad nitride layer and the insulating layer by performing a first etching process over the entire surface of the semiconductor substrate, removing the pad nitride layer by performing a second etching process, and forming a polysilicon layer on the entire surface of the semiconductor substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and constitute a part of this application, illustrate embodiment(s) of the invention and along with the description serve to explain the principle of the invention. In the drawings:

FIG. 1 is a cross-sectional illustration of a shallow trench isolation (STI) formed by a conventional method of fabricating a semiconductor device;

FIG. 2A to FIG. 2F are cross-sectional views illustrating an exemplary method of fabricating a semiconductor device according to a first embodiment of the present invention; and

FIG. 3A to FIG. 3C are cross-sectional views illustrating an exemplary method of fabricating a semiconductor device according to a second embodiment of the present invention.

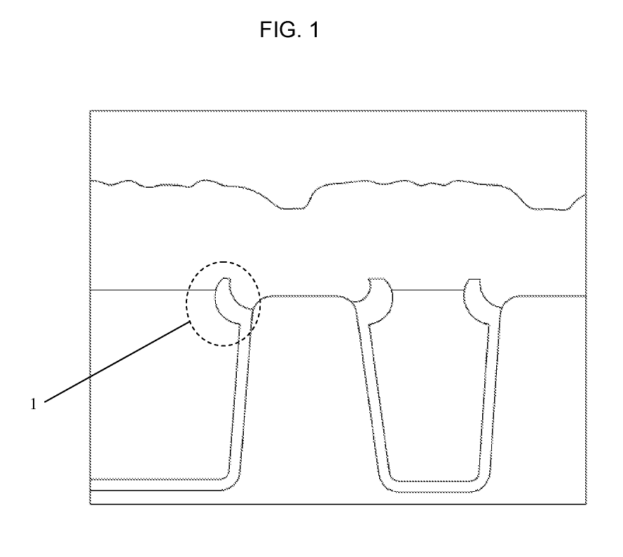

### DETAILED DESCRIPTION OF THE INVENTION

Reference will now be made in detail to embodiments of the present invention, examples of which are illustrated in the accompanying drawings. Since the structures and operations disclosed herein are explained by way of example, the technical scope of the present invention is not limited thereto.

Hereinafter, an exemplary method of fabricating a semiconductor device according to embodiments of the present invention will be explained in detail with reference to the accompanying drawings.

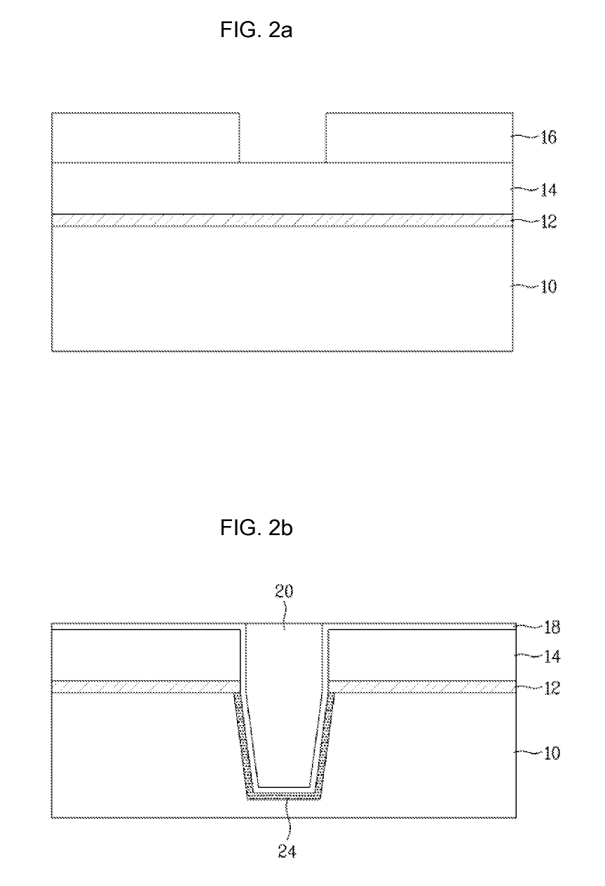

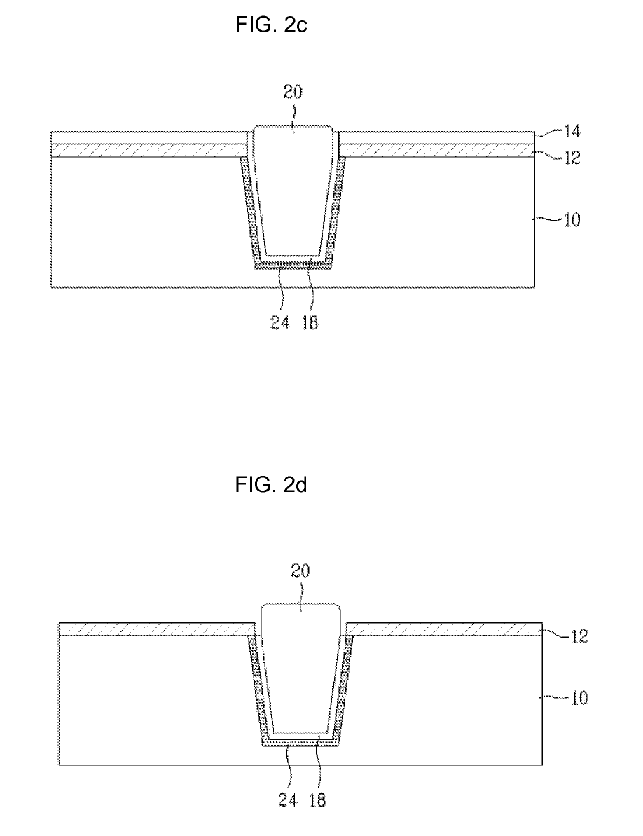

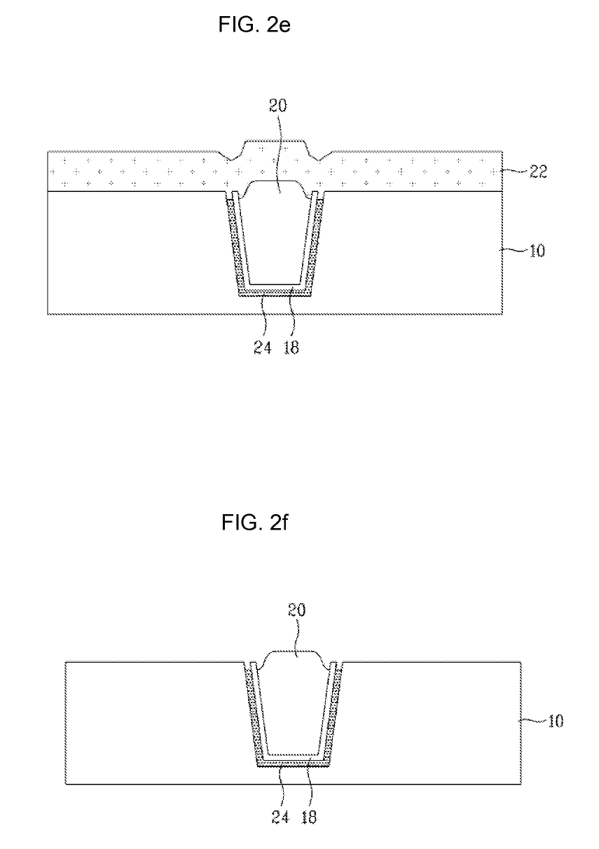

FIGS. 2A to 2F are cross-sectional views illustrating a method of fabricating a semiconductor device according to a first embodiment of the present invention.

As shown in FIG. 2A, first, a pad oxide layer 12 is formed on a semiconductor substrate 10 (which may be a single-crystal silicon wafer, or a single-crystal silicon wafer with one or more layers of epitaxial silicon grown thereon), and a pad nitride layer 14 is deposited thereon. The pad oxide film 12 may be formed by wet or dry thermal oxidation of the semiconductor substrate or chemical vapor deposition (CVD; e.g., low pressure CVD [LPCVD] or plasma enhanced CVD [PECVD]). For example, the pad oxide film 12 may be formed by CVD using tetraethylorthosilicate (TEOS) or silane (e.g., SiH₄) as a silicon source and dioxygen (O₂) and/or ozone (O₃) as an oxygen source. The pad nitride film 14 may be formed by physical vapor deposition (PVD; e.g., sputtering) or CVD (e.g., PECVD or LPCVD). Next, a photoresist (e.g., a negative or a positive photoresist) is deposited by CVD. Alternatively, the photoresist may be spin coated onto the substrate. The photoresist is then patterned by an exposure and development process to define a shallow trench isolation (STI) region, thereby forming a photoresist pattern 16 that exposing a region of the semiconductor substrate 10 where the device isolation layer will be formed.

Next, as shown in FIG. 2B, the pad nitride 14 is etched using the photoresist pattern 16 as a mask. The pad nitride layer 14 may be etched anisotropically using a plasma etching technique (e.g., reactive ion etching [RIE]). Subsequently, the pad oxide layer 12 and the semiconductor substrate 10 are selectively etched using the etched pad nitride layer 14 as an etching mask. Accordingly, a device isolation trench is formed in the device isolation region of the semiconductor device. Next, the photoresist pattern 16 is removed through a photoresist stripping or asking process.

Next, the trench T is filled with an oxide layer as an insulating layer 20. Here, a liner oxide layer 18 is formed on the entire surface of the semiconductor substrate 10 including the inside of the trench T before filling the trench T with the insulating layer 20. The liner oxide layer 18 may be formed by CVD (e.g., LPCVD or PECVD of TEOS or silane, as described above). The liner oxide layer 18 may improve contact between the inside of the trench T and the insulating oxide layer 20. Additionally, the insulating layer 20 formed of the oxide layer is thickly deposited by CVD (e.g., LPCVD or PECVD) on an upper surface of the semiconductor 10 having the trench T to fill the trench T. After the trench T is filled, the insulating layer 20 is planarized to form an insulating layer pattern by a chemical mechanical polishing (CMP) process. Accordingly, a device isolation layer including the insulating layer pattern is formed.

Here, after formation of the trench T and prior to formation of the liner oxide layer 18, a trench oxide layer 24 may be formed on the bottom and wall of the trench T by performing an oxidation process (e.g., wet or dry thermal oxidation of the semiconductor substrate) to recover a lattice damaged during the step of forming the trench T by etching the semiconductor substrate 10.

Next, as shown in FIG. 2C, the pad nitride layer 14, the liner oxide layer 18 and the insulating layer 20 are selectively etched by dry etching (e.g., RIE) the entire surface of the resulting structure. Here, the pad nitride layer 14 is dry-etched so that a predetermined thickness of the pad nitride layer 14 remains. The selective etching ratio of the pad nitride layer 14 with respect to the pad oxide layer 12 may be from 1:1 to 1:5 (e.g., 1:2 to 1:5), according to exemplary embodiments. Such dry etching may be performed in a plasma, using a (hydro)fluorocarbon etchant (e.g., of the formula CxHyFz, where x is from 1 to 4, y is 0 or a positive integer, z is an integer of at least 3, and y+z=2x or 2x+2), optionally in the presence of one or more additional etching agents, such as hydrogen, fluorine, CO, etc.

Next, as shown in FIG. 2D, the pad nitride layer 14 is completely removed by wet etching (e.g., with phosphoric acid). During this, the liner oxide layer 18 may also be partially etched at positions corresponding to upper corners of the isolation trench T and the insulating layer 20.

Referring to FIG. 2E, a second wet etching is additionally performed (e.g., using hydrofluoric acid), thereby completely removing the pad oxide layer 12. Subsequently, a gate polysilicon layer 22 is formed (e.g., by LPCVD, PECVD, or low temperature CVD) over the entire surface of the semiconductor substrate 10.

Referring to FIG. 2F, next, portions of the gate polysilicon layer 22 are removed by dry etching (e.g., RIE) according to a predetermined pattern (e.g., defined by a photolithographically irradiated and developed photo-resist).

According to the above structure of the first embodiment, since the pad nitride layer 14 is removed through a combination of dry etching and wet etching, a divot depth of the device isolation layer at the upper corners of the trench may be reduced as desired. Also, a residue of the gate polysilicon layer 22 is removed at the corners of the device isolation layer after the dry-etching of the gate poly 22.

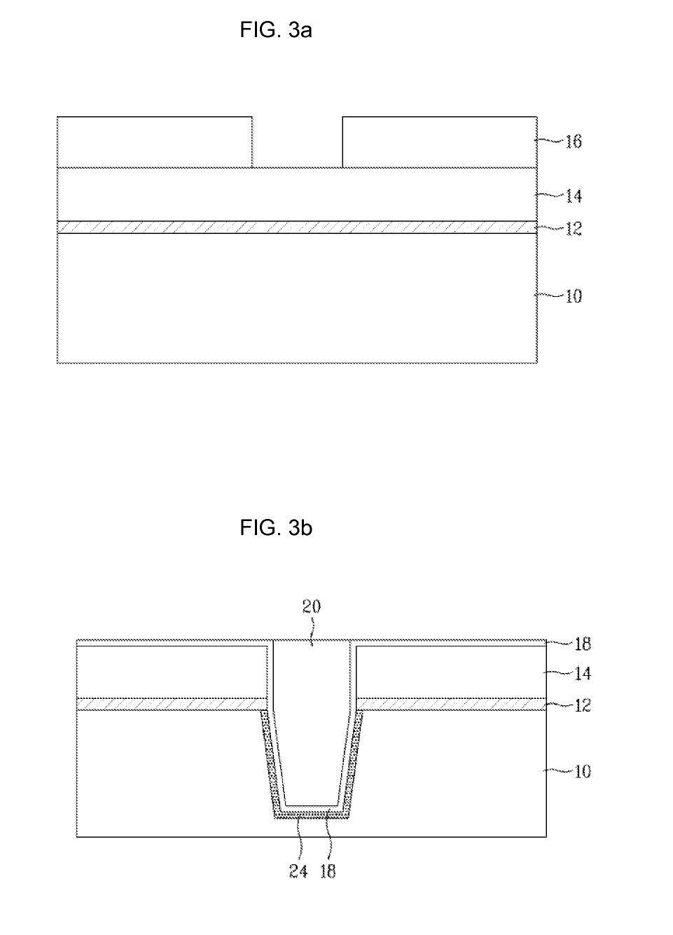

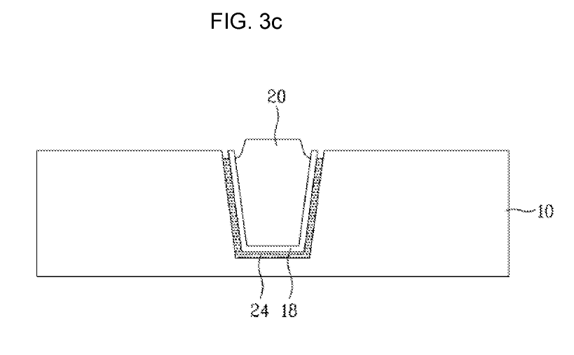

FIG. 3A through FIG. 3C are views illustrating a method of fabricating a semiconductor device according to a second exemplary embodiment of the present invention.

The structures and elements as in the first embodiment will be denoted by the same reference numerals in FIG. 3A to FIG. 3C.

As shown in FIG. 3A first, a pad oxide layer 12 is formed on a semiconductor substrate 10, and a pad nitride layer 14 is deposited thereon, as described above. The pad nitride layer 14 may be formed to a thickness of about 40˜1500 Å. A photoresist is deposited and then patterned by an exposure and development process to expose an STI region, thereby forming a photoresist pattern 16 that exposes a region of the semiconductor substrate 10 where the device isolation layer will be formed.

Next, as shown in FIG. 3B, the pad nitride 14 is etched using the photoresist pattern 16 as a mask. The pad oxide layer 12 and the semiconductor substrate 10 are selectively etched using the etched pad nitride layer 14 as an etching mask to form a trench T in the device isolation region of the semiconductor device. Next, the photoresist pattern 16 is removed through a photoresist stripping or asking process.

After formation of the trench T and prior to formation of the liner oxide layer 18, a trench oxide layer 24 may be optionally formed on the bottom and sidewalls of the trench T by performing an oxidation process (e.g., wet or dry thermal oxidation of the semiconductor substrate) to recover the crystal lattice that may have been damaged during the step of forming the trench T by etching the semiconductor substrate 10 and form a chemically compatible and strongly bound surface for further deposition of the insulator.

Next, the trench T is filled with an oxide layer as an insulating layer 20. Here, a liner oxide layer 18 is formed (e.g., by methods described above) over the entire surface of the semiconductor substrate 10 including the inside of the trench T before filling the trench T, in order to improve contact between the inside of the trench T and the insulating oxide layer 20. Subsequently, the insulating layer 20 formed of the oxide layer is thickly deposited through a CVD process (as described above) on an upper surface of the semiconductor 10 including the trench T, accordingly filling the inside of the trench T. After the trench T is filled, the insulating layer 20 is planarized to form an insulating layer pattern by a CMP process. Accordingly, a device isolation layer including the insulating layer pattern is formed.

Next, as shown in FIG. 3C, the pad nitride layer 14 and the pad oxide layer 12 are completely removed through wet etching (e.g., using phosphoric acid, which may be diluted with deionized water and which may have a temperature of from 50° C. to 90° C.). During this process, the liner oxide layer 18 may be partially etched due to excessive etching, at positions corresponding to upper corners of the isolation trench T and the insulating layer 20.

Further steps in the method of the second embodiment are the same as in the first embodiment and therefore will not be recapitulated here.

According to the second embodiment, since the pad nitride layer is deposited to the minimum thickness, a portion of the pad nitride layer to be wet etched can be minimized when the pad nitride layer is removed. Therefore, the divot depth of the device isolation layer may be further reduced. In addition, the gate polysilicon layer may be prevented from remaining at the corners of the device isolation layer after the dry etching.

As apparent from the above description, in accordance with a method of fabricating a semiconductor device according to any one of the above-described embodiments of the present invention, since a pad nitride layer is removed through a combination of dry etching and wet etching, a divot depth of the device isolation layer at the upper corners of the isolation trench T and the isolation layer 20 may be reduced. Also, a residue of the gate polysilicon layer does not form at the corners of the device isolation layer.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method of fabricating a semiconductor device, comprising:
forming a pad oxide layer and a paid nitride layer sequentially on a semiconductor substrate;
forming a trench by selectively etching the pad oxide layer, the pad nitride layer, and the semiconductor substrate;
filling the trench by depositing an insulating layer in the trench;
selectively etching the pad nitride layer and the insulating layer in a first blanket etching process;
removing the pad nitride layer in a second etching process; and
forming a polysilicon layer over the entire surface of the semiconductor substrate.

2. The method according to claim 1, further comprising forming a liner oxide layer over the entire surface of the semiconductor substrate, including an inside of the trench, prior to depositing the insulating layer in the trench.

3. The method according to claim 1, wherein the pad nitride layer has a thickness of about 400˜800 Å.

4. The method according to claim 1, wherein the first etching process comprises dry etching.

5. The method according to claim 4, wherein the dry etch has an etching ratio of the pad nitride layer to the pad oxide layer in a range of 1:1 to 1:5.

6. The method according to claim 1, wherein the first etching process comprises etching a predetermined thickness of the pad nitride layer, wherein a partial thickness of the pad nitride layer remains.

7. The method according to claim 1, wherein the second etching process comprises wet etching.

8. The method according to claim 1, wherein forming the trench comprises:
forming a photoresist pattern on the pad nitride layer to expose a trench region;
etching the pad nitride layer using the photoresist pattern as a mask; and
forming the trench by etching the pad oxide layer and the semiconductor substrate using the pad nitride layer as a mask.

9. The method according to claim 1, further comprising dry etching portions of the polysilicon layer to form a gate pattern.

10. The method according to claim 2, wherein the second etching process comprises partially etching the liner oxide layer at upper corners of the insulating layer.

11. The method according to claim 2, further comprising forming a trench oxide layer on a bottom and sidewalls of the trench prior to forming the liner oxide layer.
